(19) United States
(12) Patent Application Publication
(10) Pub. No.: US 2006/0197538 A1
(43) Pub. Date: Sep. 7, 2006

(54) Self-test method for antennas

(75) Inventors: Marko Leinonen, Oulu (FI); Seppo Rousu, Oulu (FI)

Correspondence Address: SQUIRE, SANDERS & DEMPSEY L.L.P., 14TH FLOOR, 8000 TOWERS CRESCENT, TYSONS CORNER, VA, 22182, US

(73) Assignee: Nokia Corporation

(21) Appl. No.: 11/136,387

(22) Filed: May 25, 2005

Related U.S. Application Data
(60) Provisional application No. 60/658,826, filed on Mar. 7, 2005.

(51) Int. Cl. G01R 31/11

(52) U.S. Cl. 324/533; 324/642

(57) ABSTRACT

The present invention relates to a radio communication apparatus for checking antenna interface connections of first antenna means of the radio communication apparatus, wherein a predetermined signal is transmitted at a frequency within a reception band of the first antenna means by using a second antenna means of the radio communication apparatus. The transmitted predetermined signal is received through the first antenna means to obtain a reception output which is compared with the predetermined signal. Thereby, a self-test option can be provided in the communication apparatus, e.g. mobile phone, so that no extra components are required during manufacturing and antenna operation can be continuously monitored during usage.

### FIELD OF THE INVENTION

The present invention relates to a radio communication apparatus and a method for checking operability of first antenna means thereof. In particular, the present invention relates to a self-test method for checking connection quality of antenna connections for cellular communication systems.

### BACKGROUND OF THE INVENTION

Antennas represent a key element in mobile communications as interface between the system and the air. This transition between guided waves and radiated waves involves all wireless systems and must be carried out in an effective way. In this sense, communication systems are deeply dependent on the antenna performance. Therefore, small connection errors or other antenna errors may have such a negative influence on the system performance that the communication link can be lost.

New antenna subsystems with multifunction, multiband etc. will be able to satisfy the necessities for emerging multimedia applications. Typical mobile phones nowadays have triple-band functionality requiring a 3-band antenna. Additionally, mobile terminals will provide increasing functionality such as WCDMA (Wireless Code Division Multiple Access) as well as non-cellular applications. To achieve this, several multi-band antennas will be required, e.g., quad-band GSM (Global System for Mobile Communication) antennas, WCDMA antennas, ISM (Industrial Scientific and Medical) band antennas for WLAN (Wireless Local Area Network) or Bluetooth, GPS (Global Positioning System) antennas, DVB-H (Digital Video Broadcasting—Handheld) antennas, FM (Frequency Modulation) radio antennas and RF-ID (Radio Frequency Identification) antennas and new coming systems e.g. Flarion, WiMax, Galileo.

In modern production systems, antenna assembly is performed at a labeling stage or label place of manufacturing. However, at the label place there are usually no measurement instruments available. Therefore, a problem arises how to test these antennas in production and in customer care service centers in an easy way at low cost and multiple times with high reliability.

Antennas need feeding connections from printed wired board (PWB) to antenna. Dipole antenna may have one PWB connection, but generally antennas have at least two PWB connections, at least one for RF signal feeding and at least one for grounding. However, the Antenna system functionality is degraded and not working as tested if any of these connections is poor or disconnected. Degraded performance depends on which of numerous connections is disconnected. E.g., feeding pin degradation is more severe than grounding pin degradation. In possible failure modes, one or more connections can be disconnected. E.g., poor connections can be located in the same antenna or in different antennas.

Known methods for detecting a fault of an antenna in radio transmitters have been proposed e.g. in JP9229980, JP5136747, GB2390262, JP58178645 and U.S. Pat. No. 5,144,250, wherein a directional coupler is used to detect both signals of travelling wave power and reflecting wave power. In particular, the power sent from the radio transmitter to an antenna and the power reflected from the antenna are measured by directional coupler. The reflected wave power is detected and

compared to a predetermined reference value. The ratio between the reflected power and the reference value indicates antenna faults. However, this method needs additional circuitry to measure reflected power. Moreover, transmitter this method is not useful in connection with antennas which have separate feeding for the receiver.

### SUMMARY OF THE INVENTION

It is therefore an object of the present invention to provide an improved radio communication apparatus and method for testing such an apparatus, by means of which antenna failures, such as poor or missing antenna contacts can be reliably detected without requiring additional hardware circuits.

This object is achieved by a method for checking antenna interface connections and antenna performance of an antenna of a multi-frequency communication apparatus, said method comprising the steps of:
a) transmitting a predetermined signal at a predetermined frequency of a transmitter of said radio-frequency communication apparatus;
b) receiving said transmitted predetermined signal through a receiver of said radio-frequency communication apparatus to obtain a reception output; and
c) comparing said reception output with said predetermined transmitted signal.

Additionally, the above object is achieved by a multi-antenna communication apparatus for checking antenna interface connections and antenna performance of an antenna of said multi-frequency communication apparatus, said apparatus comprising:
a) means for transmitting a predetermined signal at a predetermined frequency of a transmitter of said radio-frequency communication apparatus;
b) means for receiving said transmitted predetermined signal through a receiver of said multi-frequency communication apparatus to obtain a reception output; and
c) means for comparing said reception output with said predetermined transmitted signal.

Accordingly, poor or missing antenna contacts can be detected in a simple manner without requiring specific test equipment or measuring instruments. Antenna and antenna connections can even be tested without extra components of the communication apparatus, since the method or procedure can be implemented by a pure software routine. With the proposed self-test method, information about isolation between antennas can be collected and based on collected information and predetermined thresholds, failing antennas or antenna connections can be isolated.

The predetermined signal may be a continuous wave signal, e.g. a sine signal or communication signal It may be transmitted at a level lower than a spurious signal level mentioned in the related communication system specification or regulatory requirement for the spurious transmission outside of the communication frequency band.

Furthermore, the comparing step may comprise calculating an insertion loss between a transmitting means for transmitting the predetermined signal and a receiving means for receiving the transmitted predetermined signal and generating the reception output. The calculated insertion loss may be stored. There may be several threshold values for the multiple failure mechanisms. Each individual failure mechanisms have a different threshold value for detection.

The checking method may be performed when the multi-antenna communication apparatus is powered up or during the normal operation. This checking may be done also when certain application is started and relevant RF is powered up. Then, an error message may be generated to a user, when the comparing step leads to the result that the first antenna is not properly operating. As a particular example, the error message may be displayed on a corresponding screen. Another example may be that if connection is degraded at one of the service provider's RF band then the mobile may generate emergency call at another service provider frequency band or at the other service provider RF band as a roaming call. Other possibility is that emergency call is done in different operational mode e.g. GSM mode is not used for emergency call but instead WCDMA call is made.

The predetermined signal may be transmitted in a guard band. This guard band can be located between a communication channel and an edge of the reception band. Thereby, the spurious signal will harm other communication procedures as little as possible.

The predetermined signal may be transmitted at the normal operational receiving and transmitting bands. As an example European WCDMA transmitter transmits at the normal transmission band (1920-19080 MHz) and GSM1900 is receiving at the normal reception band (1910-1990 MHz). In this case transmission and reception bands suitable are overlapping.

Also it is possible that this predetermined signal is transmitted outside of the normal operational band. As an example GPS antenna connection may be checked with GSM1800 transmitter when the transmission frequency is set to be GPS reception band. Normal operational transmission frequency for GSM1800 is 1710-1785 MHz when GPS reception frequency is 1575.42 MHz.

Furthermore, the checking method may be initiated in response to an output of an acceleration sensor. This provides the advantage that a self-test is automatically initiated after the communication apparatus or terminal device has been dropped.

The timings of the transmitting step and the receiving step may be synchronized. This synchronization may be controlled by setting the timings so that the transmitting step is the only transmission at that time.

The above method steps may be implemented by providing a computer program product with code means for performing these steps when loaded into a memory of a computer device.

### BRIEF DESCRIPTION OF THE DRAWINGS

The present invention will now be described based on preferred embodiments with reference to the accompanying drawings in which:

FIG. 1 shows a schematic block diagram of a multi-antenna transceiver according to a first preferred embodiment;

FIG. 2 shows a typical PIFA antenna construction;

FIG. 3 shows two PIFA antennas at the same PWB;

FIG. 4 shows a schematic block diagram of a multi-antenna transceiver according to a second preferred embodiment with wireless connectivity receiver;

FIG. 5 shows a schematic block diagram of a multi-antenna transceiver according to a third preferred embodiment with wireless connectivity receiver;

FIG. 6 shows a schematic block diagram of a multi-antenna transceiver according to a fourth preferred embodiment with modified antenna switch;

FIG. 7 shows a schematic diagram indicating how different systems can be cross-tested;

FIG. 8 shows a schematic block diagram of a multi-antenna transceiver according to a fifth embodiment; and

FIG. 9 shows an alternative schematic block diagram of a multi-antenna transceiver according to a sixth embodiment.

### DESCRIPTION OF THE PREFERRED EMBODIMENTS

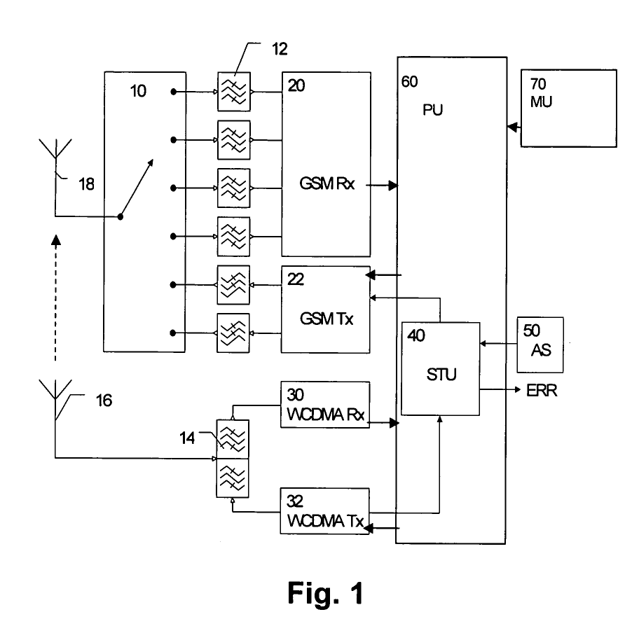

The preferred embodiments will now be described on the basis of a combined GSM and a WCDMA mobile phone front-end architecture or transceiver implemented as shown in the first preferred embodiment of FIG. 1.

In particular, the FIG. 1 shows a full-duplex mobile phone front-end architecture or transceiver wherein the WCDMA duplex bands comprise a receiving band ranging from 2110 MHz to 2170 MHz and a transmission band ranging from 1920 MHz and 1980 MHz. The WCDMA signals are received by a separate WCDMA antenna 16 which is directly connected to a WCDMA duplexer 14 con-Fig.d to switch WCDMA signals received via a common transmission and receiving path to the upper receiving path, and to switch WCDMA transmission signals received via the lower transmission path to the WCDMA antenna 16 via the combined transmitting and receiving path.

Furthermore, a GSM front-end portion is shown, in which GSM signals received via GSM antenna 18 are selectively connected by a GSM antenna switch 10 to different transmission (Tx) and Receiving (Rx) channels of four different GSM bands (quad-band GSM) ranging around 850 MHz, 900 MHz, 1800 MHz and 1900 MHz. Selective signal processing is achieved by providing a bank of filter circuits 12 for filtering transmission and reception bands. The antenna switch 10 may be based on e.g. GaAs technologies, such as PHEMT (Pseudomorphic High Electron Mobility Transistor), or CMOS (Complimentary Metal Oxide Semiconductor) technologies, such as SOI (Silicone-On-Insulator) or SOS (Silicone-On-Sapphire, a special case of SOI where sapphire is used as insulator). The GSM receiving channels are connected to a GSM receiver 20, and the GSM transmitting channels are connected to a GSM transmitter 22. Similarly, the upper branch at the WCDMA duplexer 14 is connected to a WCDMA receiver 30, and the lower branch at the WCDMA duplexer 14 is connected to a WCDMA transmitter 32. WCDMA transmitter 32, WCDMA receiver 30, GSM transmitter 22 and GSM receiver 20 are connected to a processor unit 60. The processing of the transmitted and received signals is done in the processor unit 60.

The following table summarizes cellular standards and other system frequency bands. “TX” meaning transmission and “RX” meaning reception:

| System | TX band | | RX band | |
|---|---|---|---|---|
| GSM 800 | 824 . . . 849 | MHz | 869 . . . 894 | MHz |
| GSM 900 | 890 . . . 915 | MHz | 935 . . . 960 | MHz |
| EGSM 900 | 880 . . . 915 | MHz | 925 . . . 960 | MHz |
| DCS 1800 | 1710 . . . 1785 | MHz | 1805 . . . 1880 | MHz |
| PCS1900 | 1850 . . . 1910 | MHz | 1930 . . . 1990 | MHz |
| CdmaOne | 824 . . . 849 | MHz | 869 . . . 894 | MHz |
| CdmaOne | 1850 . . . 1910 | MHz | 1930 . . . 1990 | MHz |
| EU WCDMA | 1920 . . . 1980 | MHz | 2110 . . . 2170 | MHz |
| EU WCDMA | 1850 . . . 1910 | MHz | 1930 . . . 1990 | MHz |
| WLAN 802.11B | 2400 . . . 2483.5 | MHz | 2400 . . . 2483.5 | MHz |
| Bluetooth | 2402 . . . 2480 | MHz | 2402 . . . 2480 | MHz |

| | | | |
|---|---|---|---|
| GPS | — | 1575.42 ± 5 | MHz |
| DVB-H | | 470-702 | MHz |

The circuit arrangement of FIG. 1 can be implemented as a single switch module which includes the antenna switch 10, the bank of filters 12 and the WCDMA duplexer 14, so that the whole system can be optimized for proper matching. The switch module can be implemented as a multiband/multimode antenna switch module, for example a GSM and WCDMA engine. Physically, the switch module can be a wire-bonded or flip-chipped die on a laminate organic or LTCC (Low Temperature Co-fired Ceramic) board which may also include the wire-bonded or flip-chipped bare die or chip scaled filters. The matching could be integrated into the board or integrated passive die could be used.

According to the first preferred embodiment, a self-test unit 40 is provided which controls the WCDMA transmitter 32 to transmit a signal via the EUWCDMA antenna 16 within the reception band of the GSM1900 system, so that this test signal can be received via the GSM antenna 18 and routed to the GSM receiver 20. The output signal of the GSM receiver 20 is then fed back to the self-test unit 40. In the present example, the WCDMA transmitter 32 is controlled to transmit a continuous wave (CW) test signal, such as sine signal, at a frequency within the GSM reception band. This CW test signal may be transmitted at a level lower than the allowed spurious signal level of the WCDMA system, e.g. lower than −30 dBm. This level of −30 dBm is derived from spurious emission specification for the spurious transmissions outside the WCDMA transmission band specified in 3GPP specification. Also this predetermined signal may be a normal WCDMA communication signal, which is received during normal WCDMA transmission during normal operation.

As an example, the CW test signal may be transmitted at a level of −80 dBm. This spurious test signal can be transmitted within the reception band in normal use mode.

In general, the terms “spurious signals” or “spurious emissions” are used here to designate signals or emissions transmitted on a frequency or frequencies that are outside the bandwidth necessary for communication. Such emissions or signals may include harmonic emissions and inter-modulation products.

The transmitted spurious test signal is detected by the GSM receiver 30 and the reception output is forwarded to the self-test unit 40. Due to the fact that the self-test unit 40 knows the level of the transmitted test signal, it can compare it with the received signal level and insertion loss between WCDMA transmitter 32 and GSM receiver 20 can be calculated and evaluated for checking operability of the WCDMA antenna 16 and GSM antenna 18.

This self-test system can be used during the research and development (R&D) phase of the apparatus, e.g. mobile phone, to measure accurate antenna isolation between the two antennas 16, 18. The measured isolation can then be stored in a memory 70 of the mobile phone for comparison purposes. The memory 70 may be any suitable memory provided in connection with the processing means of the mobile phone. The spurious transmission of the test signal can be done in a very fast manner, so that the spurious signal will not remain active after detection via the GSM receiver 20 and the self-test unit 40. Thereby, disturbance of other communications can be minimized.

Moreover, the self-test unit 40 can be configured for use in connection with any kind of antenna connection, wherein a self-test can be initiated when the mobile phone is powered up. If the self-test fails, then the mobile phone or terminal device can advise the user by a corresponding error message ERR that there is an antenna connection problem. In particular, the terminal device may give information to the user in a visual or audible manner if the antenna connection is not working properly, e.g. emergency call is not working in WCDMA mode but works in GSM mode.

Another possibility is that an error message is sent to the service provider that these terminal antennas are not operating properly. Using a properly working uplink connection to an operator can do this error message sending. This kind of error reporting of the antenna performance may be advantageous in a CDMA system where the whole system is based on accurate power level reporting.

The frequency of the spurious test signal can be set to the reception frequency band in such a manner that it will harm as little as possible other communications. As an example, the spurious test signal can be transmitted at a frequency located within the guard band between the first communication channel and the reception band edge of the WCDMA system.

The checking or test operation of the self-test unit 40 can be based on a received signal strength measuring (RSSI) which normally is calibrated during the production phase of the mobile phone at room temperature. Thereby, the signal level can be measured relatively accurately. If the measured antenna, e.g. the WCDMA antenna 16, is not connected, then the received signal strength detected by the self-test unit 40 considerably deviates from the signal strength of a fully working or operable antenna connection, e.g. by more than 20 dB, which can be detected very easily.

In current systems, the antenna existence and performance measurement is done by means of an external coupler in the test equipment. In currenly used systems, an own measurement coupler is needed for all RF bands. However, the accuracy of coupler measurements is worse than RSSI accuracy. Thus, with the proposed self-test procedure, coupler measurement is no longer necessary and the required couplers can be dispensed with, which safes production costs. Also, as an advantage for this self-test antenna, testing can be done during other RF functionality testing and this takes less than 1 ms time.

According to the preferred embodiment, the mobile phone may be equipped with an accelometer sensor 50 or another kind of acceleration sensor. When the mobile phone drops and the accelometer sensor 50 detects this, a signal is supplied to the self-test unit 40 which initiates the self-test procedure in response to this. If the antenna connection is poor or damaged after a drop, the time of dropping is stored in the memory 70 and this information can be used at a service center or during service inspection. Also other type of sensors may trigger self-test sequence, e.g., moisture, pressure or temperature sensors that detects ambient environmental change.

As an additional feature, antenna-related field failure rate (FFR) can be monitored easily by regularly initiating the self-test procedure at the self-test unit 40. Implementation into the mobile phone can easily be achieved, if the GSM system and the WCDMA system are controlled by the same processor unit 60 and the same processing code. Spurious transmission time and reception times can then be synchronized in an easy manner.

It is noted that the self-test unit 40 not necessarily has to be implemented as a separate hardware unit, but can be realized as a software routine controlling a processor device which is already provided in the mobile phone. The preferred embodiment may thus be implemented by a simple computer program loaded into the memory of the mobile phone. In this case, block 60 of FIG. 1 represents a usual processor unit and block 70 represents a memory of the mobile phone.

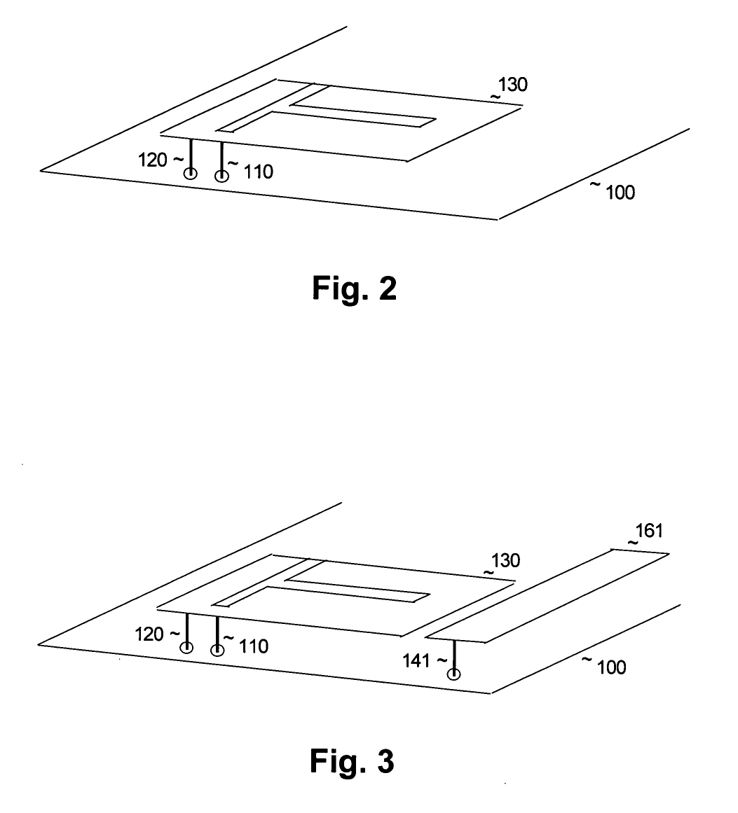

FIG. 2 shows a typical cellular mobile phone antenna. This antenna type is a planar inverted antenna (PIFA), where the actual antenna resonator 130 is placed upon the PWB 100. The shown antenna has two separate resonances, which make it possible to work at two RF band e.g. GSM900 and GSM1800. The actual RF feeding pin is shown in FIG. 2 at 120. The pin 110 is a ground pin which is needed to ground the resonator plate. This antenna is a realization or implementation of the GSM antenna 18 shown in FIG. 1. There may be several actual feeding pins and ground pins in the antenna construction but for the illustration purposes only one is shown.

FIG. 3 shows another example of a PIFA antenna with one radiator element more than the antenna presented in FIG. 2. The pin 141 represents a second RF feed pin,. A second antenna resonator 161 is provided for this additional antenna. This kind of second radiator element can be used for WCDMA and/or Bluetooth and/or GPS antenna construction in the multi-antenna device. There may be several actual feeding pins and ground pins in the antenna construction but for the illustration purposes only one feeding pin (141) is shown.

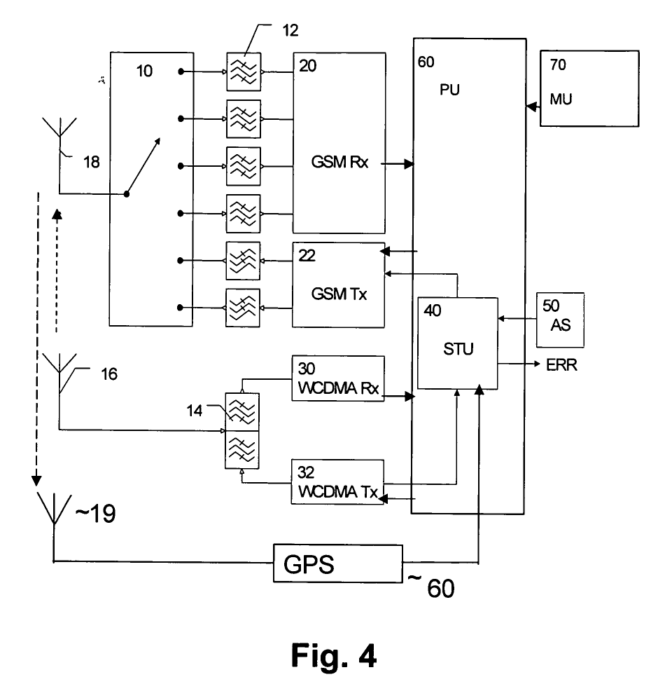

FIG. 4 shows a multi-antenna device according to the second preferred embodiment where GPS is integrated to the device of FIG. 1.

In FIG. 4, a self-test unit 40 is provided which controls the GSM transmitter 22 to transmit a signal via the GSM antenna 18 at the GSM1800 band out of the normal operational transmission band so that GSM1800 transmission is at the reception band of a GPS receiver 60. The test signal transmission can be received via the GPS antenna 19 and routed to the GPS receiver 60. The output signal of the GPS receiver 60 is then fed back to the self-test unit 40.

The transmitted spurious test signal is detected by the GPS receiver 60 and the reception output is forwarded to the self-test unit 40. Due to the fact that the self-test unit 40 knows the level of the transmitted test signal, it can compare it with the received signal level and insertion loss between GSM transmitter 22 and the GPS receiver 60 can be calculated and evaluated for checking operability of the GSM antenna 18 and the GPS antenna 19.

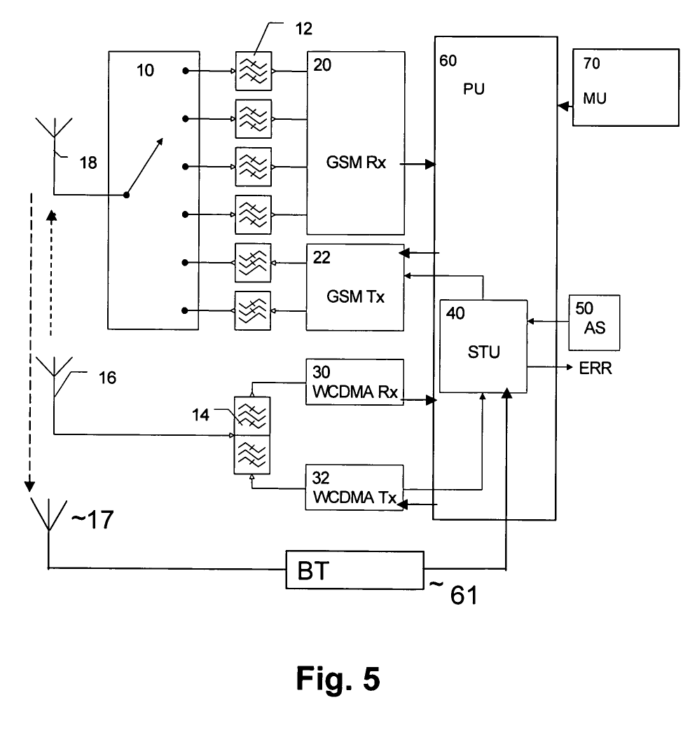

FIG. 5 shows a multi-antenna device according to the third preferred embodiment, where Bluetooth is integrated to the device of FIG. 1. According to the third preferred embodiment, a self-test unit 40 is provided which controls the GSM transmitter 22 to transmit a signal via the GSM antenna 18 at the lowest channels of the GSM850 band, so that the third harmonic of the GSM850 test signal transmission can be received via the Bluetooth antenna 17 and routed to a Bluetooth receiver 61. The output signal of the Bluetooth receiver 61 is then fed back to the self-test unit 40.

The transmitted spurious test signal is detected by the Bluetooth receiver 61 and the reception output is forwarded to the self-test unit 40. Due to the fact that the self-test unit 40 knows the level of the transmitted test signal, it can compare it with the received signal level and insertion loss between GSM transmitter 22 and Bluetooth receiver 61 can be calculated and evaluated for checking operability of the GSM antenna 18 and the Bluetooth antenna 17.

The second antenna of FIG. 3 may correspond to the WCDMA antenna 18 in FIG. 1 and/or to the GPS antenna 19 in FIG. 4 and/or to the Bluetooth antenna 17 in the FIG. 5.

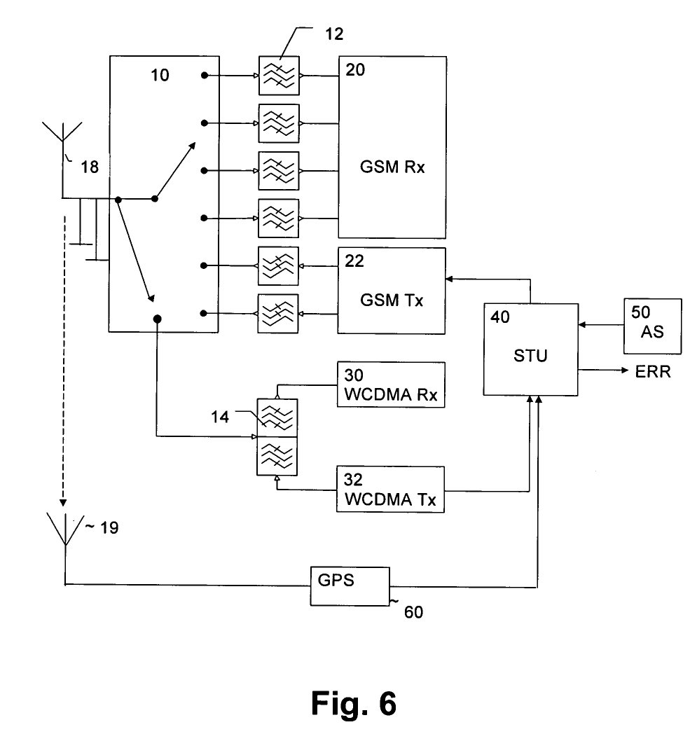

FIG. 6 shows an alternative front-end module or device according to the fourth preferred embodiment, which has multiple switches in the same module. When there are multiple switches in the same module one of the transmitters and one of the receivers can be connected together. If the are poor connections in the antenna module, in one of the antenna module pins, this has an effect on the insertion loss between transmitter and receiver. This change of the insertion loss can be detected and distinguished according to the magnitude of the loss failure type.

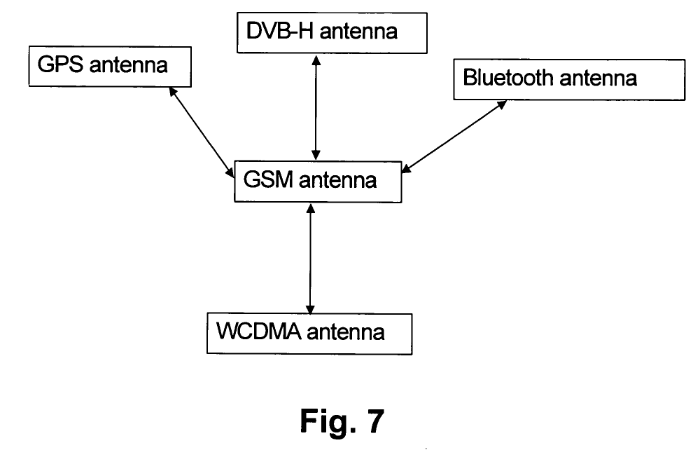

Since there are multiple transceivers and antennas in the product, antenna connections can be cross-tested. In FIG. 7 shows a schematic diagram indicating how different systems may be cross-tested. The actual cross testing can be done with the method mentioned previously. The testing can be done by testing each arrow individually, and if one of the connections is not working properly, then the actual poor connection can be traced by making other measurements with other antennas and systems. The advantage of this cross testing is that mobile phone service centers can reach correct conclusions faster and more accurately than by changing antenna by antenna.

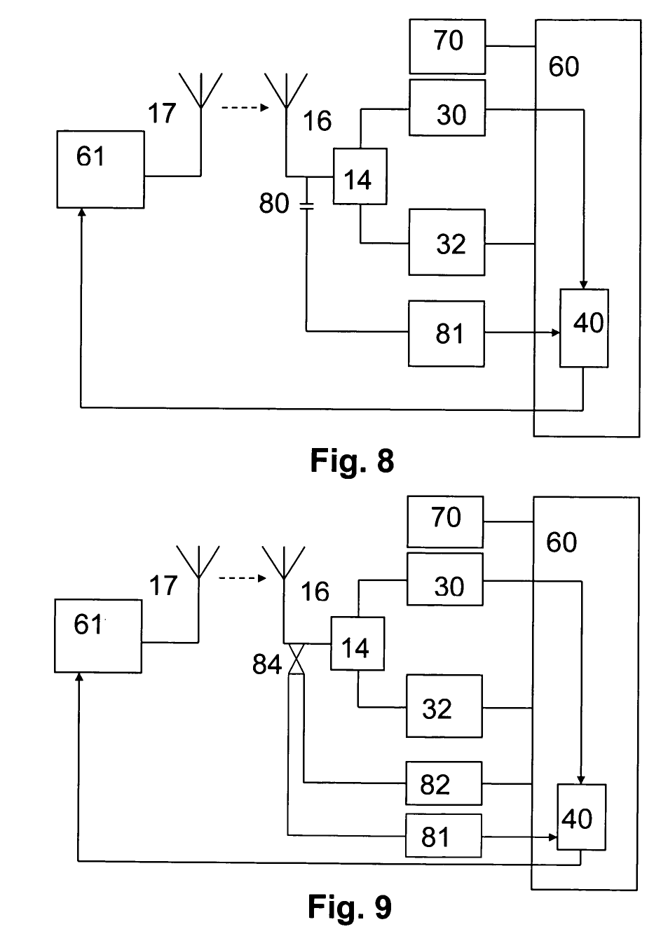

FIG. 8. shows a schematic block diagram of a multi-antenna transceiver according to a fifth embodiment using an alternative method to accomplish antenna connection testing. In the fifth embodiment, the other system's normal receiver is not used but instead the other system power detection circuitry 80, 81 is used to receive the pre-determined test signal. The system works as follows. The Bluetooth transmitter 61 transmits via the Bluetooth antenna 17 a predetermined test signal at a predetermined frequency and at the predetermined RF power level. The WCDMA receiver 30 receives the signal through the WCDMA antenna 16. The power detection circuitry 80, 81 converts the RF power level to the corresponding detected signal value. The power detection circuitry 80, 81 contains a power decoupling element 80 and an RF-to-DC rectifier circuitry 81. The power decoupling element 80 takes samples of the transmitted power. The power decoupling element 80 can be implemented by a decoupling capacitor or by a directional coupler. In FIG. 8 a capacitor-based solution is shown. The RF-to-DC rectifier circuitry 81 converts the incoming RF signal to a corresponding DC voltage, which is routed to the processing unit 60 and to the self-test unit 40. The RF-to-DC rectifier circuitry 81 converts the RF signal to the base band signal, which is then filtered in a suitable way to obtain a DC value.

The antenna isolation can be calculated in the self-test unit 40 since it knows the transmitted Bluetooth RF power and receives the received RF signal strength from the DC voltage supplied by the RF-to-DC rectifier circuitry 81. The RF power and corresponding DC voltage value from the RF-to-DC rectifier circuitry 81 can be tested during product R&D phase and a corresponding DC value to RF-power table can be stored in the memory unit 70. The pre-determined test signal can be received via the WCDMA receiver 30 and via the power detection circuitry 80,81. The information via both receivers can be combined in a suitable way to improve the accuracy of the antenna insertion loss calculation.

FIG. 9 shows a schematic block diagram of a multi-antenna transceiver according to a sixth embodiment, where a directional coupling element 84 is used to take samples of the transmitted power and the reflected power from the WCDMA antenna 16. If the decoupling element is implemented by the directional decoupling element 84, then there will be need for two RF-to-DC rectifier circuitries 81, 82. A first RF-to-DC rectifier circuitry 81 is used for the antenna self-testing purposes and a second RF-to-DC rectifier circuitry 82 is used for normal WCDMA transmission controlling.

It is to be noted that the present invention is not restricted to the above preferred embodiment and can be implemented in any mobile phone or other wireless communication device having at least two antenna systems. Each of the systems can then be tested in a similar way. The first system is used for transmitting with a first antenna at a reception frequency of the second system. The spurious transmission level can be adjusted so that the spurious emission limits of the reception band of the second system are not exceeded. Furthermore, the actual spurious transmission can be timed so that the spurious emission is the only transmission at that time and signal strength can be measured as fast as possible.

Additionally, any kind of test signal can be used which must not necessarily be a spurious signal. It can be transmitted within the normal transmission and reception bands as long as adequate measures are taken to prevent disturbance of running communications. Furthermore, the proposed self-test procedure can be used in connection with any kind of antenna for wireless communication devices, as initially mentioned. The preferred embodiments may thus vary within the scope of the attached claims.

Although the present invention has been described with reference to specific exemplary embodiments, it will be evident that various modifications and changes may be made to these embodiments without departing from the broader spirit and scope of the invention as set forth in the claims. Accordingly, the specification and drawings are to be regarded in an illustrative rather than restrictive sense.

1. A method for checking antenna interface connections of a radio frequency communication apparatus, said method comprising the steps of:
a) transmitting a predetermined signal at a predetermined frequency of a transmitter of said radio frequency communication apparatus;
b) receiving said transmitted predetermined signal through a receiver of said radio-frequency communication apparatus to obtain a reception output; and
c) comparing said reception output with said transmitted predetermined signal.

2. The method according to claim 1, wherein said transmitter and said receiver are connected to a same physical antenna.

3. The method according to claim 1, wherein said transmitter and said receiver are each using an associated antenna.

4. The method according to claim 1, wherein said transmitted predetermined signal is a continuous wave signal.

5. The method according to claim 1, wherein said transmitted predetermined signal is a communication signal.

6. The method according to claim 5, wherein said communication signal comprises at least one of a voice call signal, a data call signal and any other signaling signal.

7. The method according to claim 1, where said transmitted predetermined signal comprises a fundamental frequency signal.

8. The method according to claim 1, where said transmitted predetermined signal comprises a harmonic frequency signal.

9. The method according to claim 1, wherein said transmitted predetermined signal is transmitted at a normal transmission system frequency band.

10. The method according to claim 1, wherein said transmitted predetermined signal is transmitted outside a normal frequency system band.

11. The method according to claim 1, wherein said transmitted predetermined signal is transmitted at a normal reception frequency system band.

12. The method according to claim 1, wherein said transmitted predetermined signal is received at a normal reception system frequency band.

13. The method according to claim 1, wherein said transmitted predetermined signal is received outside a normal frequency system band.

14. The method according to claim 1, wherein said transmitted predetermined signal is transmitted at a lever lower than an allowed maximum spurious signal level at a used transmission band.

15. The method according to claim 1, wherein said transmitted predetermined signal is transmitted at a level lower than an allowed maximum spurious signal level at a used reception band.

16. The method according to claim 1, wherein said transmitted predetermined signal is transmitted at a level lower than an allowed maximum spurious signal level outside used communication system bands.

17. The method according to claim 1, wherein said comparing step comprises calculating an insertion loss between a transmitting means for transmitting said predetermined signal and a receiving means for receiving said transmitted predetermined signal and generating said reception output.

18. The method according to claim 17, further comprising the step of storing said calculated insertion loss.

19. The method according to claim 17, further comprising the step of comparing said calculated insertion loss to a predetermined threshold value.

20. The method according to claim 19, wherein said predetermined threshold value is stored in a terminal device during production.

21. The method according to claim 17, wherein said predetermined threshold value is determined previously by a terminal device.

22. The method according to claim 17, wherein several threshold values are provided for different antenna connection failure mechanisms.

23. The method according to claim 1, wherein said checking method is performed when a multi-antenna communication apparatus is powered up.

24. The method according to claim 1, wherein said checking method is performed when a predetermined communication system is activated.

25. The method according to claim 17, further comprising the step of generating an error message to a user or using a properly working uplink connection to an operator or a service provider when said comparing step leads to a result that an antenna is not properly operating.

26. The method according to claim 25, wherein said error message is displayed.

27. The method according to claim 1, wherein said checking method is initiated in response to an output of a sensor

28. The method according to 27, where said sensor comprises an acceleration sensor.

29. The method according to 27, wherein said sensor comprises a moisture sensor.

30. The method according to claim 1, further comprising the step of synchronizing timings of said transmitting step and said receiving step.

31. The method according to claim 30, further comprising the step of setting said timing so that said transmitting step is the only transmission at that time.

32. The method according to claim 1, wherein multiple individual antenna measurements are done and an antenna with a poor connection is isolated based on said antenna measurements.

33. The method according to claim 1, wherein said receiver of radio-frequency apparatus is a power detection circuitry.

34. The method according claim 1, wherein the predetermined ignal is received with the power detection circuitry.

35. The method according to claim 34, wherein information from the power detection circuitry is compared to the said transmitted predetermined signal power.

36. The method according the claim 1, wherein information of the pre-determined signal is received via the receiver and via a power detection circuitry, wherein individual pieces of information can be combined in a suitable way.

37. A computer program product embodied within a computer-readable medium, when loaded into a memory of a computer device, said computer program produce comprising code means for performing the steps of:
a) transmitting a predetermined signal at a predetermined frequency of a transmitter of said radio frequency communication apparatus;
b) receiving said transmitted predetermined signal through a receiver of said radio frequency communication apparatus to obtain a reception output; and
c) comparing said reception output with said transmitted predetermined signal.

38. A radio communication apparatus for checking antenna interface connections of an antenna of a radio frequency communication apparatus, said apparatus comprising:
a) means for transmitting a predetermined signal at a predetermined frequency of a transmitter of said radio frequency communication apparatus;
b) means for receiving said transmitted predetermined signal through a receiver of said radio frequency communication apparatus to obtain a reception output; and
c) means for comparing said reception output with said transmitted predetermined signal.

39. The apparatus according to claim 38, wherein said transmitter and said receiver are connected a same physical antenna.

40. The apparatus according to claim 38, wherein said transmitter and said receiver are each using an associated antenna.

41. The apparatus according to claim 38, wherein said transmitted predetermined signal is a continuous wave signal.

42. The apparatus according to claim 38, wherein said transmitted predetermined signal is a communication signal.

43. The apparatus according to claim 42, wherein said communication signal comprises at least one of a voice call signal, a data call signal and any other signaling signal.

44. The apparatus according to claim 38, where said transmitted predetermined signal comprises a fundamental frequency signal.

45. The apparatus according to claim 38, where said transmitted predetermined signal comprises a harmonic frequency signal.

46. The apparatus according to claim 38, wherein said transmitted predetermined signal is transmitted at a normal transmission system frequency band.

47. The apparatus according to claim 38, wherein said transmitted predetermined signal is received at a normal reception system frequency band.

48. The apparatus according to claim 38, wherein said transmitted predetermined signal is received outside a normal frequency system band.

49. The apparatus according to claim 38, further comprising storing means for storing a calculated insertion loss.

50. The apparatus according to claim 38, further comprising comparing means for comparing a calculated insertion loss to a predetermined threshold value.

51. The apparatus according to claim 50, wherein said predetermined threshold value is stored in a terminal device.

52. The apparatus according to claim 50, wherein said predetermined threshold value is determined previously by a terminal device.

53. The apparatus according to claim 50, wherein several threshold values are provided for different antenna connection failure mechanisms.

54. The apparatus according to claim 38, wherein a first antenna means comprises a WCDMA antenna and a second antenna means comprises a GSM antenna.

55. The apparatus according to claim 38, wherein a first antenna means comprises a GSM antenna and a second antenna means comprises a Bluetooth antenna.

56. The according to claim 38, wherein a first antenna means comprises a GSM antenna and a second antenna means comprises a GPS antenna.

57. The apparatus according to claim 38, wherein a first antenna means comprises a GSM antenna and a second antenna means comprises a DVB-H antenna.

58. The apparatus according to claim 38, wherein said communication apparatus comprises a mobile phone, smart phone, PDA or laptop computer.

59. The apparatus according to claim 38, wherein said receiver of radio-frequency apparatus is a power detection circuitry.

60. The apparatus according claim 59, wherein the predetermined signal is received with the power detection circuitry.

61. The apparatus according to claim 59, wherein the information from the power detection circuitry is compared to the said transmitted predetermined signal power.

62. The apparatus according to claim 59, wherein the predetermined signal is received by the power detection circuitry through a decoupling element.

63. The apparatus according to claim 62, wherein the decoupling element is implemented with a capacitor.

64. The apparatus according the to claim 62, wherein the decoupling element is implemented with a directional coupler.

65. The apparatus according the claim 38, wherein information of the predetermined signal is received via the receiver and via a power detection circuitry.
